(19) United States
(12) Patent Application Publication
(10) Pub. No.: US 2016/0231390 A1
(43) Pub. Date: Aug. 11, 2016

(54) BATTERY ABNORMALITY INDICATION APPARATUS

(71) Applicant: Toyota Jidosha Kabushiki Kaisha, Toyota-shi (JP)

(72) Inventor: Kazuhiko Sakakibara, Toyota-shi (JP)

(21) Appl. No.: 15/007,864

(22) Filed: Jan. 27, 2016

(30) Foreign Application Priority Data
Feb. 9, 2015 (JP) 2015-023556

(51) Int. Cl. G01R 31/36

(52) U.S. Cl. CPC G01R 31/3689; G01R 31/3662; G01R 31/3679

(57) ABSTRACT

A battery abnormality indication apparatus includes a measurement sensor that measures a state of a battery; an electronic control unit that determines, based on the state of the battery acquired from the measurement sensor, whether the battery has abnormality; and an indicator that indicates abnormality of the battery when the electronic control unit determines that the battery has abnormality. When the electronic control unit determines that a used amount of the battery is less than a predetermined amount, the indicator indicates a first abnormality indication showing a fault of the battery, and, when the electronic control unit determines that the used amount of the battery is greater than or equal to the predetermined amount, the indicator indicates a second abnormality indication showing degradation of the battery.

### CROSS-REFERENCE TO RELATED APPLICATIONS

The present application is based on and claims the benefit of priority of Japanese Priority Application No. 2015-023556, filed on Feb. 9, 2015, the entire contents of which are hereby incorporated herein by reference.

### BACKGROUND

1. Field

The present disclosure relates to a battery abnormality indication apparatus.

2. Description of the Related Art

In the related art, a technology is known where, based on an internal resistance of a battery, it is determined whether the battery has abnormality, and abnormality is indicated (for example, see Japanese Laid-Open Patent Application No. 60-140163).

### SUMMARY

According to one aspect of the present disclosure, a battery abnormality indication apparatus includes a measurement sensor that measures a state of a battery; an electronic control unit that determines, based on the state of the battery acquired from the measurement sensor, whether the battery has abnormality; and an indicator that indicates abnormality of the battery when the electronic control unit determines that the battery has abnormality. When the electronic control unit determines that a used amount of the battery is less than a predetermined amount, the indicator indicates a first abnormality indication showing a fault of the battery, and, when the electronic control unit determines that the used amount of the battery is greater than or equal to the predetermined amount, the indicator indicates a second abnormality indication showing degradation of the battery.

Other objects, features and advantages of the present disclosure will become more apparent from the following detailed description when read in conjunction with the accompanying drawings.

### BRIEF DESCRIPTION OF THE DRAWINGS

FIG. 1 is a block diagram illustrating one example of a configuration of a battery abnormality indication apparatus;

FIG. 2 is a flowchart illustrating one example of operations of the battery abnormality indication apparatus;

FIG. 3 is a flowchart illustrating another example of operations of the battery abnormality indication apparatus;

FIG. 4 is a flowchart illustrating yet another example of operations of the battery abnormality indication apparatus;

FIG. 5 illustrates one example of a temporal change in an internal resistance;

FIG. 6 illustrates one example of relationships between an estimated value of a battery voltage and a charged amount; and

FIG. 7 illustrates one example of relationships between a battery voltage and a charged ratio.

### DETAILED DESCRIPTION OF THE EMBODIMENTS

For the purpose of convenience, the description of the above-mentioned related art will be continued first.

In the related art, abnormality is indicated in the same manner between a case where a battery degrades due to an increase in the used amount (for example, aged deterioration) and a case where a fault occurs in the battery such that an electrode column is damaged, or so. Therefore, a user cannot understand whether abnormality is indicated due to degradation in the battery or a fault of the battery.

An object of the embodiments is to provide a battery abnormality indication apparatus capable of showing a user whether abnormality is indicated due to degradation or a fault of a battery.

Below, the embodiments will be described with reference to the drawings.

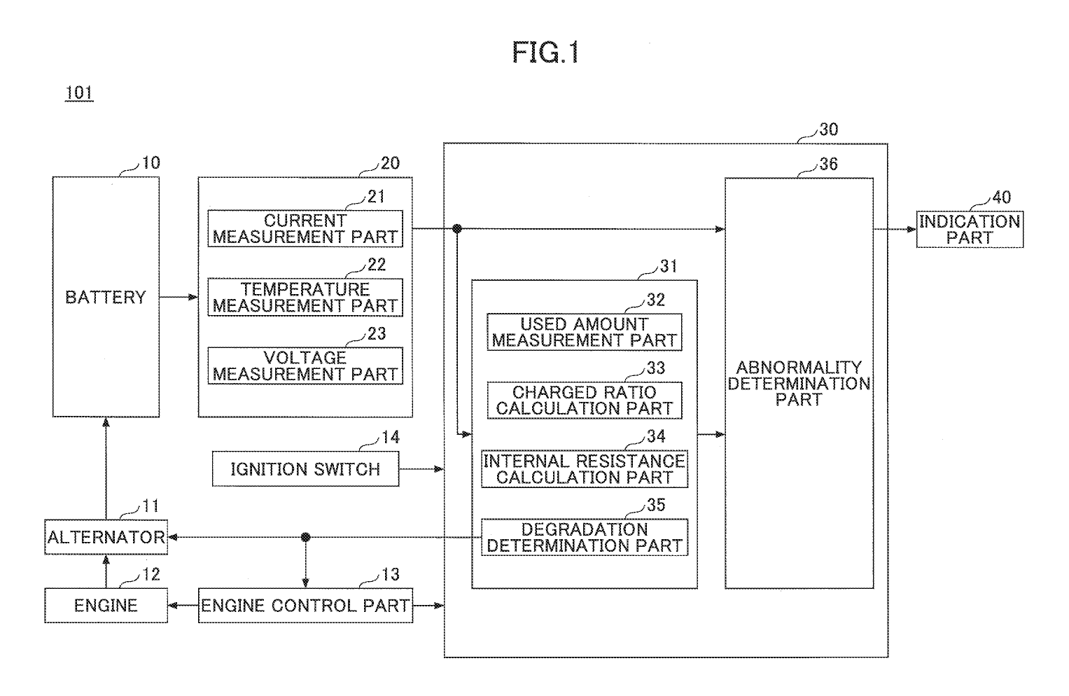

FIG. 1 is a block diagram illustrating one example of a configuration of a battery abnormality indication apparatus 101 according to one embodiment. The battery abnormality indication apparatus 101 is, for example, an apparatus mounted in a vehicle such as an automobile, and has a function of indicating abnormality of a battery 10 mounted in the vehicle. The battery abnormality indication apparatus 101 includes, for example, the battery 10, a measurement sensor or measurement part 20, a control part 30, and an indicator 40.

The battery 10 is one example of a secondary battery capable of supplying power to a load installed in the vehicle (for example, the measurement part 20, the control part 30, the indicator 40, and so forth). The battery 10 is charged by a power generation device, for example, an alternator 11. The alternator 11 is a generator generating power as a result of being rotated in synchronization with, for example, an engine 12 that is a power source of the vehicle. The battery 10 is a source to supply power to start the engine 12. As a specific example of the battery 10, a lead battery can be cited.

An engine control part 13 is one example of an engine control part for starting the engine 12. As a specific example of the engine control part 13, an engine ECU starting the engine 12 in response to an ignition switch 14 being turned on, an idling-stop ECU controlling idling stop of the engine 12, or so, can be cited.

The measurement part 20 is one example of a battery state measurement part measuring a state of the battery 10 (the battery state). The measurement part 20 has, for example, a current measurement part 21, a temperature measurement part 22, and a voltage measurement part 23. As specific examples of the battery state, the battery current, the battery temperature, the battery voltage, and so forth, can be cited. The engine control part 13 can be included in the measurement part 20.

The current measurement part 21 is one example of a current measurement part measuring the current flowing through the battery 10 (the battery current). The current measurement part 21 is, for example, a current sensor measuring the charging current or the discharging current flowing through the battery 10.

The temperature measurement part 22 is one example of a temperature measurement part measuring the temperature of the battery 10 itself or the ambient temperature of the battery 10 (the battery temperature). The temperature measurement part 22 is, for example, a temperature sensor measuring the battery temperature.

The voltage measurement part 23 is one example of a voltage measurement part measuring the voltage of the battery 10 (the battery voltage). The voltage measurement part 23 is, for example, a voltage sensor measuring the battery voltage.

The control part 30 is one example of a control part determining whether the battery 10 has abnormality based on the battery state acquired from of the measurement part 20. The control part 30 is, for example, an Electronic Control Unit (ECU) having a detection part 31 and an abnormality determination part 36. The respective functions of the detection part 31 and the abnormality determination part 36 are implemented by, for example, a microcomputer having a Central Processing Unit (CPU).

The detection part 31 is one example of a battery state detection sensor detecting a battery state other than the battery current, the battery temperature, and the battery voltage. As specific examples of “a battery state other than the battery current, the battery temperature, and the battery voltage”, the used amount, the charged ratio, the internal resistance, the degradation degree, and so forth, of the battery 10, for example, can be cited (which will be described later in detail).

The detection part 31 has, for example, a used amount measurement part 32, a charged ratio calculation part 33, an internal resistance calculation part 34, and a degradation determination part 35.

The used amount measurement part 32 is one example of a measurement sensor measuring the used amount of the battery 10 based on the battery state acquired from at least one of the measurement part 20 and the engine control part 13. When the battery 10 is replaced, the used amount measurement part 32 resets the used amount of the battery 10, and starts measuring the used amount of the battery 10 that has been thus replaced with.

As a specific example of the used amount of the battery 10, the accumulated value of the charged and discharged amount of the battery 10, the number of start times of the engine 12 started with power supplied by the battery 10, the used period of time of the battery 10, or so, can be cited.

The used amount measurement part 32 measures the accumulated value of the charged and discharged amount of the battery 10 by, for example, accumulating the current value of the battery current acquired by the current measurement part 21 from when manufacturing the vehicle is completed (for example, from when the battery 10 is first mounted). The accumulated value of the charged and discharged amount of the battery 10 is a value acquired from accumulating the absolute value of the current value of the charging current and the absolute value of the current value of the discharging current of the battery 10.

It is also possible that the used amount measurement part 32 counts the number of start times of the engine 12 by, for example, acquiring starting information of the engine 12 from the engine control part 13. It is also possible that the used amount measurement part 32 measures the used period of time of the battery 10 by, for example, measuring the elapsed time from when manufacturing the vehicle is completed, for example, from when the battery 10 is mounted in the vehicle.

The charged ratio calculation part 33 is one example of a charged ratio calculation part calculating the charged ratio of the battery 10 based on the measurement result of the battery state acquired from the measurement part 20. The charged ratio calculation part 33 calculates, for example, a State of Charge (SOC) indicating the charged ratio of the battery 10. “SOC” is a value defined by, for example, “(remaining capacity of battery 10 (A·s))/(fully charged capacity of the battery 10 (A·s))×100(%)”.

The charged ratio calculation part 33 calculates the charged ratio based on the battery voltage measured by the voltage measurement part 23 in a state where, for example, the alternator 11 is not operated, corrects the thus calculated charged ratio using at least one of the battery temperature and the battery current, and thus, calculates the accurate charged ratio. Note that the actual method of calculating the charged ratio of the battery 10 by the charged ratio calculation part 33 can be any method.

The internal resistance calculation part 34 is one example of an internal resistance calculation part calculating the internal resistance of the battery 10 based on the measurement result of the battery state acquired from the measurement part 20. The internal resistance calculation part 34 calculates the internal resistance of the battery 10 by, for example, dividing the battery voltage measured by the voltage measurement part 23 by the battery current measured by the current measurement part 21. It is possible that the internal resistance calculation part 34 corrects the calculated internal resistance using at least one of the charged ratio of the battery 10 and the battery temperature, and thus, calculates the accurate internal resistance. Note that the actual method of calculating the internal resistance of the battery 10 by the internal resistance calculation part 34 can be any method.

The degradation determination part 35 is one example of a degradation determination part determining the degradation degree of the battery 10. An increase in the degradation degree calculated by the degradation determination part 35 indicates that the degradation of the battery 10 has become worse. The actual method of calculating the degradation degree by the degradation determination part 35 can be any method. One example will be described later.

The abnormality determination part 36 is one example of an abnormality determination part determining whether the battery 10 has abnormality based on the battery state acquired from at least one of the measurement part 20 and the detection part 31. The abnormality determination part 36 determines that the battery 10 has abnormality if the battery state acquired by at least one of the measurement part 20 and the detection part 31 satisfies a predetermined abnormality determination condition.

The abnormality determination part 36 determines that the battery 10 has abnormality if, for example, the voltage measurement part 23 measures that the minimum value of the battery voltage acquired when the engine 12 is being started is less than or equal to a predetermined starting performance determination threshold Vth. The “starting performance determination threshold Vth” is a threshold for determining whether performance (starting performance of the battery 10) of the battery 10 for starting the engine 12 is degraded, and, is one example of an abnormality determination condition for determining whether the battery 10 has abnormality.

As a specific example of a variation in the internal resistance, the difference in the internal resistance between before and after a change, the change rate in the internal resistance between before and after a change (i.e., the increase rate or the decrease rate), or such, can be cited.

The indicator 40 is one example of an indicator that indicates abnormality of the battery 10 if the battery 10 is determined to have abnormality by the abnormality determination part 36 of the control part 30. As a specific example of the indicator 40, a display device, a lamp, or such, indicating abnormality information showing abnormality of the battery 10 in such a manner as to be visible by a user of the vehicle such as an occupant thereof, can be cited.

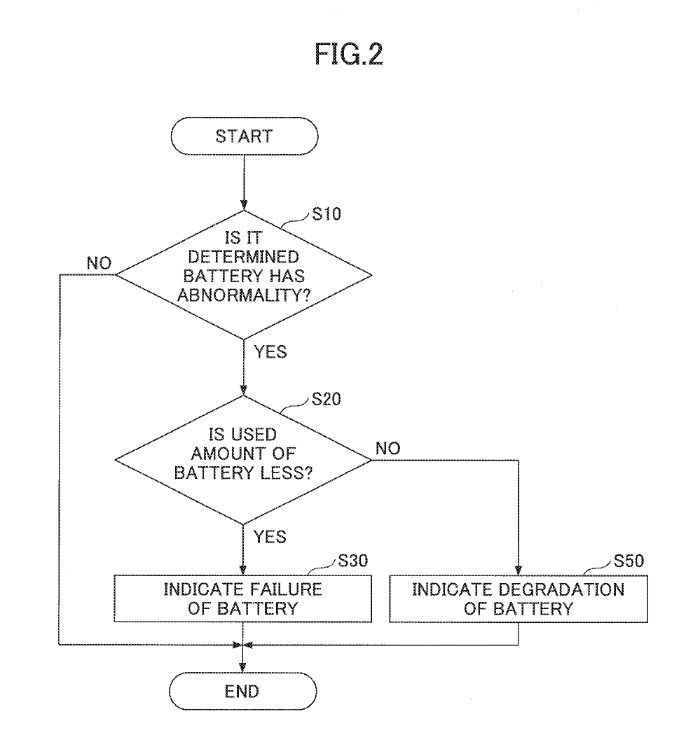

FIG. 2 is a flowchart illustrating one example of operations of the battery abnormality indication apparatus 101, and illustrating one example of a battery abnormality indication method carried out by the control part 30 of the battery abnormality indication apparatus 101.

In step S10, the abnormality determination part 36 determines whether the battery 10 has abnormality based on the battery state acquired from at least one of the measurement part 20 and the detection part 31. If the abnormality determination part 36 does not determine that the battery 10 has abnormality in step S10, the indicator 40 does not indicate abnormality of the battery 10. On the other hand, if the abnormality determination part 36 determines that the battery 10 has abnormality in step S10, the abnormality determination part 36 acquires the used amount of the battery 10 measured by the used amount measurement part 32.

In step S20, the abnormality determination part 36 determines whether the used amount of the battery 10 acquired when the battery 10 is thus determined to have abnormality is less than a predetermined amount. If the used amount of the battery 10 acquired when the battery 10 is thus determined to have abnormality is less than the predetermined amount, it is possible to determine that the abnormality of the battery 10 does not correspond to degradation due to the service lifetime of the battery 10 but corresponds to a fault due to a factor other than the lifetime of the battery 10. In contrast thereto, if the used amount of the battery 10 acquired when the battery 10 is determined to have abnormality is greater than the predetermined amount, it is possible to determine that the abnormality of the battery 10 does not correspond to a fault due to a factor other than the lifetime of the battery 10 but corresponds to degradation due to the lifetime of the battery 10.

Therefore, the indicator 40 indicates a first abnormality indication showing a fault of the battery 10 in step S30 if, for example, the abnormality determination part 36 determines in step S20 that the used amount of the battery 10 is less than the predetermined amount. On the other hand, the indicator 40 indicates a second abnormality indication showing degradation of the battery 10 in step S50 if, for example, the abnormality determination part 36 determines in step S20 that the used amount of the battery 10 is greater than or equal to the predetermined amount.

Thus, an indication of abnormality (abnormality indication) of the battery 10 is changed between a case of degradation of the battery 10 and a case of a fault of the battery 10 according to the used amount of the battery 10. Therefore, it is possible to show the user whether the abnormality indication of the battery 10 is carried out due to degradation or is carried out due to a fault. As a result, it is possible to prevent a user from misunderstanding as if, for example, abnormality of the battery 10 corresponds to a fault due to a factor other than the lifetime although the abnormality of the battery 10 actually corresponds to degradation due to the lifetime. In the same way, it is possible to prevent a user from misunderstanding as if, for example, abnormality of the battery 10 corresponds to degradation due to the lifetime, although the abnormality of the battery 10 actually corresponds to a fault due to a factor other than the lifetime.

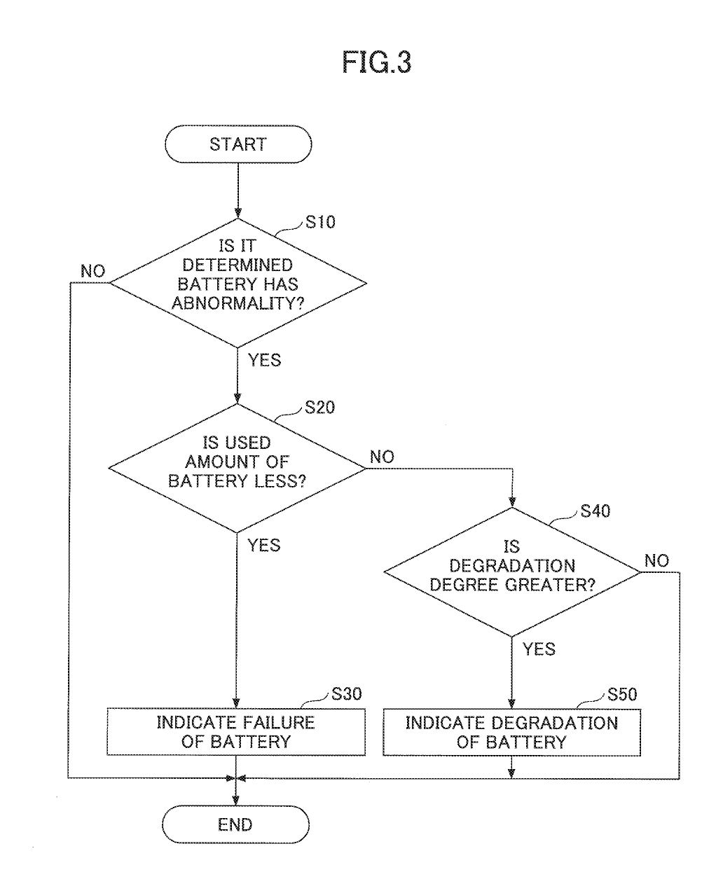

FIG. 3 is a flowchart illustrating a second example of operations of the battery abnormality indication apparatus 101, and illustrating one example of a battery abnormality indication method carried out by the control part 30 of the battery abnormality indication apparatus 101. The same points as those of FIG. 2 will be omitted appropriately while the same reference numerals are given thereto.

If the abnormality determination part 36 determines in step S20 that the used amount of the battery 10 is greater than or equal to the predetermined amount (NO in step S20) after determining in step S10 that the battery 10 has abnormality (YES in step S10), the abnormality determination part 36 acquires the degradation degree calculated by the degradation determination part 35 in step S40. In step S40, the abnormality determination part 36 then determines whether the degradation degree of the battery 10 thus acquired when abnormality determination part 36 thus determines that the battery 10 has abnormality and the used amount of the battery 10 is greater than or equal to the predetermined amount is greater than a reference value.

The abnormality determination part 36, for example, operates the alternator 11 so that the battery 10 is charged by the alternator 11 to have a charged ratio greater than or equal to a predetermined value, for determining whether the degradation degree of the battery 10 is greater than the reference value. The “charged ratio greater than or equal to the predetermined value” means, for example, a charged ratio representing the fully charged state. The “charged ratio representing the fully charged state” is, for example, 100% or a value slightly less than 100%.

The abnormality determination part 36 determines whether the battery 10 has been charged to have the charged ratio greater than or equal to the predetermined value, based on, for example, the charged ratio calculated by the charged ratio calculation part 33. The abnormality determination part 36 can determine whether the charged ratio of the battery 10 becomes equal to the charged ratio representing the fully charged state based on, for example, the drooping characteristic of the charging current flowing to the battery 10 (actually, based on whether the charging current having a current value less than or equal to a predetermined current value continues flowing for a period greater than or equal to a predetermined period of time).

During operation of the alternator 11, the voltage measurement part 23 cannot precisely detect the battery voltage. Therefore, the abnormality determination part 36 thus operates the alternator 11 whereby the battery 10 is charged to have the charged ratio greater than or equal to the predetermined value, and estimates the voltage value (the estimated voltage value Ve) of the battery voltage according to a predetermined arithmetic expression or map when the battery 10 has been thus charged to have the charged ratio greater than or equal to the predetermined value. For example, the abnormality determination part 36 estimates the estimated voltage value Ve according to a predetermined arithmetic expression or map based on a charged amount calculated from the accumulated value of the charging current of the battery 10 acquired from when the battery 10 is determined to have abnormality until the battery 10 has been charged to have the charged ratio greater than or equal to the predetermined value. Then, the abnormality determination part 36 determines whether the estimated voltage value Ve is less than a predetermined reference voltage value.

The abnormality determination part 36 can estimate that the battery voltage has not been restored to such a voltage value that the battery 10 is not determined as having abnormality (for example, a voltage value exceeding the starting performance determination threshold Vth) if the estimated voltage value Ve is less than the predetermined reference voltage value. Thus, the abnormality determination part 36 determines that the degradation degree of the battery 10 is greater than the reference value.

On the other hand, the abnormality determination part 36 can estimate that the battery voltage has been restored to such a voltage value that the battery 10 is not determined as having abnormality if the estimated voltage value Ve is greater than or equal to the predetermined reference voltage value. Thus, the abnormality determination part 36 determines that the degradation degree of the battery 10 is less than the reference value.

Thus, it is possible to determine that the degradation degree of the battery 10 has become sufficiently worse so as to show degradation of the battery 10 to a user if the degradation degree of the battery 10, acquired when the battery 10 is determined to have abnormality and the used amount of the battery 10 is determined to be greater than or equal to the predetermined amount, is greater than the reference value. In contrast thereto, it is possible to determine that the degradation degree of the battery 10 has not become sufficiently worse so as to show degradation of the battery 10 to a user if the degradation degree of the battery 10 acquired when the battery 10 is determined to have abnormality is less than the reference value.

Therefore, the indicator 40 indicates the second abnormality indication showing degradation of the battery 10 in step S50 if, for example, the abnormality determination part 36 determines that the used amount of the battery 10 is greater than or equal to the predetermined amount (NO in step S20) and the degradation degree of the battery 10 is greater than the reference value (YES in step S40). On the other hand, the indicator 40 does not carry out abnormality indication of the battery 10 if, for example, the abnormality determination part 36 determines that the degradation degree of the battery 10 is less than or equal to the reference value (NO in step S40). Thus, it is possible to clearly show a user that the degree degradation of the battery 10 has become worse to some degree, and prevent an abnormality indication showing degradation of the battery 10 from being carried out even if the degradation degree of the battery 10 has not become sufficiently worse, for example.

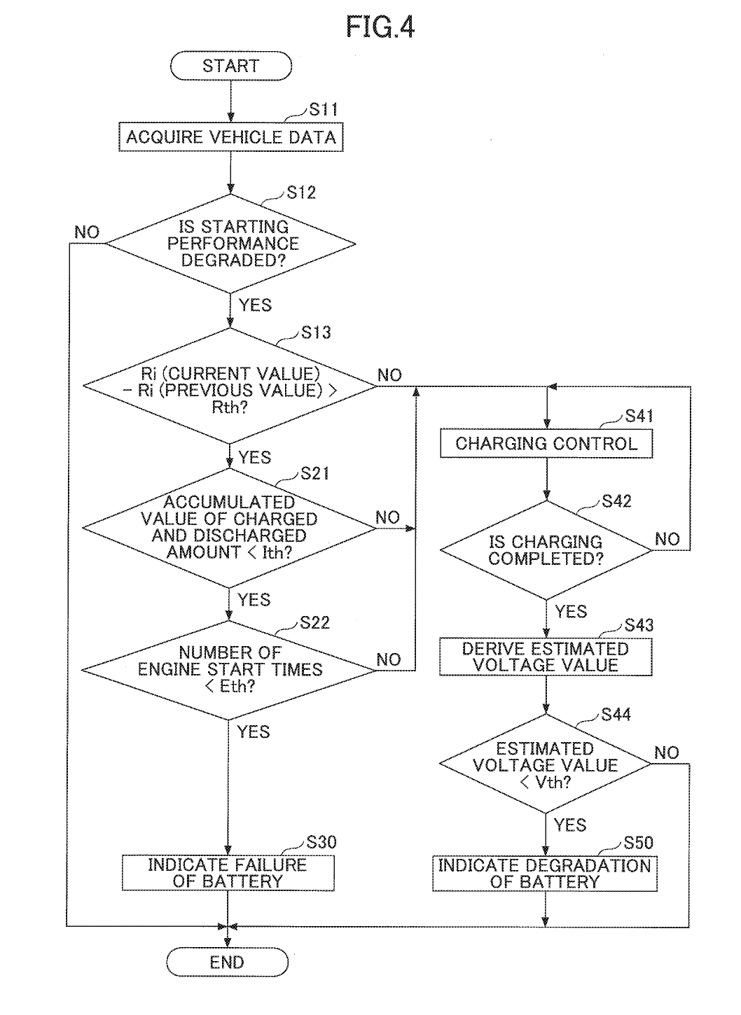

FIG. 4 is a flowchart illustrating a third example of operations of the battery abnormality indication apparatus 101, and illustrating one example of a battery abnormality indication method carried out by the control part 30 of the battery abnormality indication apparatus 101. The same points as those of FIGS. 2 and 3 will be omitted appropriately while the same reference numerals are given thereto.

In steps S11 and S12, the abnormality determination part 36 determines whether the battery 10 has abnormality, based on the battery state acquired from at least one of the measurement part 20 and the detection part 31.

In step S11, if it is detected that the ignition switch 14 is switched from its turned off state into its turned on state and the engine 12 is started with power from the battery 10, the abnormality determination part 36 acquires vehicle data including the battery state from at least one of the measurement part 20 and the detection part 31.

In step S12, the abnormality determination part 36 determines whether performance (starting performance of the battery 10) of the battery 10 for starting the engine 12 is degraded. Thereby, the abnormality determination part 36 can determine whether a starting failure of the engine 12 is beginning to occur due to degradation of the starting performance of the battery 10, and thus, can determine whether the battery 10 has abnormality. The abnormality determination part 36 determines that a fault concerning starting the engine 12 is beginning to occur if the abnormality determination part 36 determines that, for example, the starting performance of the battery 10 is degraded, and then, determines that the battery 10 has abnormality.

The abnormality determination part 36 determine that the starting performance of the battery 10 is degraded if, for example, the voltage measurement part 23 has measured that the minimum value of the battery voltage acquired when the engine 12 is being started is less than or equal to the predetermined starting performance determination threshold Vth, and then, determines that the battery 10 has abnormality. The starting performance determination threshold Vth is a threshold for determining whether the starting performance of the battery 10 is degraded, and is one example of an abnormality determination condition for determining whether the battery 10 has abnormality.

It is possible that the abnormality determination part 36 determines that the starting performance of the battery 10 is degraded and determines that the battery 10 has abnormality, if, for example, idling stop of the engine 12 is inhibited by the engine control part 13 due to the fact that the starting performance of the battery 10 is degraded. Thus, even if idling stop of the engine 12 is automatically inhibited according to the corresponding determination of the engine control part 13, a user can recognize the reason therefor, i.e., which one of a fault of the battery 10 and degradation of the battery 10 causes the inhibition, by checking an abnormality indication of the battery 10 carried out in step S30 or step S50 described later.

Note that the actual method of determining whether the starting performance of the battery 10 is degraded by the abnormality determination part 36 can be any method. For example, it is possible that the abnormality determination part 36 determines whether the starting performance of the battery 10 is degraded based on at least one of the battery temperature measured by the temperature measurement part 22, the internal resistance measured by the internal resistance calculation part 34, and the charged ratio calculated by the charged ratio calculation part 33.

The indicator 40 does not carry out an abnormality indication of the battery 10 if the abnormality determination part 36 does not determine that the starting performance of the battery 10 is degraded, in step S12. On the other hand, the abnormality determination part 36 determines, in steps S13, S21, and S22, whether the abnormality of the battery 10 corresponds to a fault, if the abnormality determination part 36 determines in step S12 that the starting performance of the battery 10 is degraded.

In step S13, the abnormality determination part 36 determines whether the variation of the internal resistance Ri calculated by the internal resistance calculation part 34 exceeds a predetermined threshold Rth.

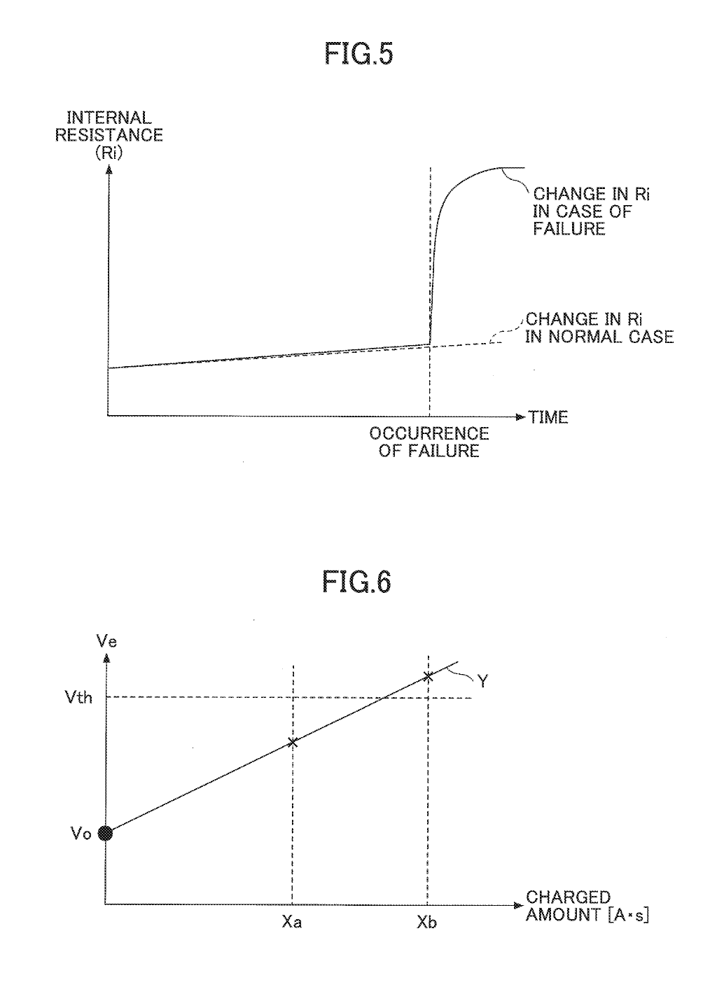

FIG. 5 illustrates one example of a temporal change in the internal resistance Ri of the battery 10. “Time” on the abscissa in FIG. 5 can be replaced with “the used amount of the battery 10”.

Whether the abnormality of the battery 10 corresponds to a fault can be determined based on the variation of the internal resistance Ri. If the starting performance of the battery 10 degrades due to degradation of the battery 10, the internal resistance Ri does not sharply change. In contrast thereto, if the starting performance of the battery 10 degrades due to a fault of the battery 10 (for example, damage of an electrode column of the battery 10), the internal resistance Ri changes sharply. Note that, if the used amount of the battery 10 (for example, the accumulated value of the charged and discharged amount of the battery 10, the number of start times of the engine 12 started by the power of the battery 10, or so) is relatively great, degradation of the battery 10 becomes worse sharply. Therefore, the internal resistance Ri may change greatly even though the battery 10 has no fault.

Therefore, the abnormality determination part 36 determines that the abnormality of the battery 10 corresponds to a fault if the abnormality determination part 36 determines that the variation of the internal resistance Ri is greater than the predetermined threshold Rth and the used amount of the battery 10 is less than or equal to a predetermined amount. Thus, the abnormality determination part 36 determines that the abnormality of the battery 10 corresponds to a fault if the variation of the internal resistance Ri is relatively great even through the battery 10 has not been used so much. The abnormality determination part 36 determines that the abnormality of the battery 10 does not corresponds to a fault if the abnormality determination part 36 determines that the used amount of the battery 10 is greater than or equal to the predetermined amount even if the abnormality determination part 36 determines that the variation in the internal resistance Ri is greater than the predetermined threshold Rth.

In step S13 of FIG. 4, a difference ΔRi is shown which is acquired by subtracting the previous value of the internal resistance Ri from the current value of the internal resistance Ri, as one example of the variation of the internal resistance Ri. In step S13, the abnormality determination part 36 compares the current value of the internal resistance Ri with the previous value of the internal resistance Ri, for example, and determines whether the difference ΔRi exceeds the predetermined threshold Rth.

The “current value of the internal resistance Ri” is the internal resistance currently calculated by the internal resistance calculation part 34, and can be a value statistically calculated using the currently calculated internal resistance and the previously calculated internal resistance (for example, the average thereof). In the same way, the “previous value of the internal resistance Ri” is the internal resistance previously calculated by the internal resistance calculation part 34, and can be a value statistically calculated using the previously calculated internal resistance and the further previously calculated internal resistance (for example, the average thereof).

By normalizing the current value of the internal resistance Ri and the previous value of the internal resistance Ri, respectively, using at least one of the specific charged ratio and battery temperature, the accuracy in determining whether the battery 10 has a fault improves.

The “current value of the internal resistance Ri” and the “previous value of the internal resistance Ri” mean, respectively, for example, the internal resistance Ri in the current trip and the internal resistance Ri in the previous trip. The “trip” means a period of time from when the ignition switch 14 is switched from the turned off state into the turned on state until the ignition switch 14 is switched from the turned on state into the turned off state. It is also possible that the “current value of the internal resistance Ri” and the “previous value of the internal resistance Ri” mean, respectively, for example, the internal resistance Ri acquired when the engine 12 was started most recently and the internal resistance Ri acquired when the engine 12 was started previously to most recently.

The abnormality determination part 36 determines that the battery 10 is determined to have abnormality due to insufficient charging of the battery 10 if the abnormality determination part 36 determines in step S13 that the difference ΔR acquired when the battery 10 is determined to have abnormality is less than or equal to the predetermined threshold Rth. Then, the abnormality determination part 36 determines that the abnormality of the battery 10 does not correspond to a fault. The abnormality determination part 36 determines the degradation degree of the battery 10 in steps S41-S44 if the abnormality determination part 36 determines in step S13 that the difference ΔR acquired when the battery 10 is determined to have abnormality is less than or equal to the predetermined threshold Rth.

On the other hand, the abnormality determination part 36 determines in steps S21 and S22 whether the used amount of the battery 10 is less than or equal to a predetermined amount, as will be described below, if the abnormality determination part 36 determines that the difference ΔR acquired when the battery 10 is determined to have abnormality is greater than the predetermined threshold Rth. The order between step S21 and step S22 can be changed.

In step S21, the abnormality determination part 36 determines whether the accumulated value of the charged and discharged amount of the battery 10 is less than a predetermined current amount Ith. In step S22, the abnormality determination part 36 determines whether the number of start times of the engine 12 is less than a predetermined number of times Eth. The abnormality determination part 36 determines that the used amount of the battery 10 is less than or equal to the predetermined amount if the accumulated value of the charged and discharged amount of the battery 10 is determined as being less than the predetermined current amount Ith and the number of start times of the engine 12 is determined as being less than the predetermined number of times Eth.

The indicator 40 indicates the first abnormality indication showing a fault of the battery 10 in step S30 if the abnormality determination part 36 determines that the variation of the internal resistance Ri of the battery 10 is greater than the predetermined threshold Rth, and also, the used amount of the battery 10 is less than or equal to the predetermined amount (YES in S13, YES in S21, and YES in S22).

On the other hand, the abnormality determination part 36 determines that the used amount of the battery 10 is greater than or equal to the predetermined amount if the accumulated value of the charged and discharged amount of the battery 10 is determined as being greater than or equal to the predetermined current amount Ith (NO in S21) or the number of start times of the engine 12 is determined as being greater than or equal to the predetermined number of times Eth (NO in S22). The abnormality determination part 36 determines that the abnormality of the battery 10 does not correspond to a fault if the used amount of the battery 10 is determined as being greater than or equal to the predetermined amount (NO in S21 or NO in S22) even if the difference AR is greater than the predetermined threshold Rth (YES in S13), and determines in steps S41 to S44 the degradation degree of the battery 10.

In steps S41-S44, the abnormality determination part 36 determines whether the battery 10 is degraded so much that it is not possible to recover from the degradation of starting performance of the battery 10.

In steps S41 and S42, the abnormality determination part 36 operates the alternator 11 in such a manner that charging control is carried out where discharging of the battery 10 is inhibited and the battery 10 is charged to have the charged ratio greater than or equal to the predetermined value. When the charging control is carried out, the abnormality determination part 36 inhibits idling stop of the engine 12, for example, and the charging voltage applied to the battery 10 is increased by the alternator 11.

When the battery 10 has been charged to have the charged ratio greater than or equal to the predetermined value and the charging control is finished, the abnormality determination part 36 derives, in step S43, the voltage value (the estimated voltage value Ve) of the battery voltage acquired when the battery 10 is charged to have the charged ratio greater than or equal to the predetermined value, using a predetermined arithmetic expression(s) or a map.

FIG. 6 illustrates one example of relationships between the charged amount and the estimated voltage value Ve. “Vo” denotes the battery voltage acquired when the starting performance of the battery 10 is determined as being degraded in step S12 of FIG. 4. “Vo” is expressed as a minimum value of the battery voltage acquired when the engine 12 is started. “Vth” denotes the starting performance determination threshold for determining whether the starting performance of the battery 10 is degraded. The abscissa denotes the charged amount X calculated from the accumulated value of the charging current of the battery 10 from when the starting performance of the battery 10 is determined as being degraded in step S12 of FIG. 4 until the battery 10 has been charged to have the charged ratio greater than or equal to the predetermined value.

The abnormality determination part 36 calculates the estimated voltage value Ve according to a linear arithmetic expression “Ve=A×B+Vo”, for example. The linear arithmetic expression “Ve=A×B+Vo” is equivalent to the linear expression Y shown in FIG. 6.

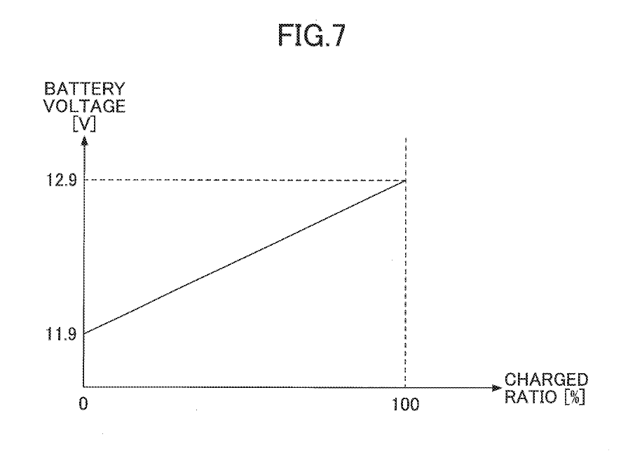

In the linear arithmetic expression “Ve=A×B+Vo”, “B” denotes “(charged amount X)/(fully charged capacity of battery 10)”. “A” denotes a constant value (for example, “1”). The reason why “A” can be defined as “1” is that, as shown in FIG. 7, the relationship shown in FIG. 6 can be approximated to such a relationship that, as the charged ratio increases 1%, the battery voltage increases 0.01 V.

In step S44 of FIG. 4, the abnormality determination part 36 determines whether the thus acquired estimated voltage value Ve is less than the starting performance determination threshold Vth. If the abnormality determination part 36 determines that the estimated voltage value Ve is less than the starting performance determination threshold Vth (if the equation X=Xa holds in FIG. 6), the abnormality determination part 36 determines that the abnormality of the battery 10 is such that the battery 10 is degraded so much that it is not possible to restore the starting performance of the battery 10. On the other hand, if the abnormality determination part 36 determines that the estimated voltage value Ve is greater than or equal to the starting performance determination threshold Vth (if the equation X=Xb holds in FIG. 6), the abnormality determination part 36 determines that the starting performance of the battery 10 has been restored through the charging control in step S41.

If the abnormality determination part 36 determines in step S44 that the estimated voltage value Ve is less than the starting performance determination threshold Vth, the indicator 40 indicates the second abnormality indication showing degradation of the battery 10 in step S50. On the other hand, if the abnormality determination part 36 determines in step S44 that the estimated voltage value Ve is greater than or equal to the starting performance determination threshold Vth, the indicator 40 does not carry out the second abnormality indication showing degradation of the battery 10.

Thus, the battery abnormality indication apparatus 101 has been described by the embodiments. However, the present disclosure is not limited to such embodiments. It is possible to make various modifications and/or improvements by combining with another embodiment(s) partially or with the entirety thereof, partially replacing with another embodiment(s), or so, within the scope of the claims.

For example, what is used to be based on when determining whether the battery 10 has abnormality is not limited to the variation in the internal resistance, and it is also possible to determine whether the battery 10 has abnormality based on the battery voltage or the battery current. It is also possible that whether the battery 10 has abnormality is determined by combining the variation in the internal resistance with another parameter(s) such as the battery voltage, the battery current, the battery temperature, the charged ratio, and/or the like.

The battery voltage when the engine 12 is started has a correlation also with the internal resistance. The greater the internal resistance is, the less the battery voltage when the engine 12 is started is. Therefore, it is possible that the estimated voltage value Ve is determined based on the internal resistance Ri, or based on both the internal resistance Ri and the charged amount X. Also, it is possible that the estimated voltage value Ve is corrected using a correction map or so according to the battery temperature.

According to the embodiments, if it is determined that a battery has abnormality in a situation where the used amount of the battery is relatively small, it is possible to consider that the abnormality of the battery does not correspond to degradation due to an increase in the used amount of the battery but corresponds to a fault. In contrast thereto, if it is determined that the battery has abnormality in a situation where the used amount of the battery is relatively great, it is possible to consider that the abnormality of the battery does not correspond to a fault but corresponds to degradation due to an increase in the used amount of the battery.

Therefore, according to the embodiments, an abnormality indication of the battery is changed between a case of degradation of the battery and a case of a fault of the battery 10 according to the used amount of the battery. Therefore, it is possible to show a user whether the abnormality indication of the battery is due to degradation or a fault.

What is claimed is:

1. A battery abnormality indication apparatus comprising:
a measurement sensor that measures a state of a battery;
an electronic control unit that determines, based on the state of the battery acquired from the measurement sensor, whether the battery has an abnormality; and
an indicator that indicates abnormality of the battery when the electronic control unit determines that the battery has abnormality, wherein
when the electronic control unit determines that a used amount of the battery is less than a predetermined amount, the indicator indicates a first abnormality indication showing a fault of the battery, and, when the electronic control unit determines that the used amount of the battery is greater than or equal to the predetermined amount, the indicator indicates a second abnormality indication showing degradation of the battery.

2. The battery abnormality indication apparatus as claimed in claim 1, wherein
the indicator indicates the second abnormality indication when the electronic control unit determines that the used amount is greater than or equal to the predetermined amount and a degradation degree of the battery is greater than a reference value.

3. The battery abnormality indication apparatus as claimed in claim 2, wherein
the electronic control unit determines that the degradation degree of the battery is greater than the reference value when the electronic control unit estimates that a voltage value of the battery, at a time when the battery is charged to have a charged ratio greater than or equal to a predetermined value, is less than a reference voltage value.

4. The battery abnormality indication apparatus as claimed in claim 3, wherein
the indicator indicates the second abnormality indication when the electronic control unit determines that the used amount is greater than or equal to the predetermined amount and estimates that the voltage value of the battery, at a time when the battery is charged to have the charged ratio greater than or equal to the predetermined value, is less than the reference voltage value.

5. The battery abnormality indication apparatus as claimed in claim 1, wherein
the indicator indicates the first abnormality indication when the electronic control unit determines that a variation in an internal resistance of the battery is greater than or equal to a predetermined threshold and determines that the used amount of the battery is less than or equal to the predetermined amount.

6. The battery abnormality indication apparatus as claimed in claim 2, wherein
the indicator indicates the first abnormality indication when the electronic control unit determines that a variation in an internal resistance of the battery is greater than or equal to a predetermined threshold and determines that the used amount of the battery is less than or equal to the predetermined amount.

7. The battery abnormality indication apparatus as claimed in claim 3, wherein
the indicator indicates the first abnormality indication when the electronic control unit determines that a variation in an internal resistance of the battery is greater than or equal to a predetermined threshold and determines that the used amount of the battery is less than or equal to the predetermined amount.

8. The battery abnormality indication apparatus as claimed in claim 4, wherein
the indicator indicates the first abnormality indication when the electronic control unit determines that a variation in an internal resistance of the battery is greater than or equal to a predetermined threshold and determines that the used amount of the battery is less than or equal to the predetermined amount.

9. The battery abnormality indication apparatus as claimed in claim 1, wherein
the used amount is an accumulated value of a charged and discharged amount of the battery or the number of start times of an engine started by power supplied by the battery.

10. The battery abnormality indication apparatus as claimed in claim 2, wherein
the used amount is an accumulated value of a charged and discharged amount of the battery or the number of start times of an engine started by power supplied by the battery.

11. The battery abnormality indication apparatus as claimed in claim 3, wherein
the used amount is an accumulated value of a charged and discharged amount of the battery or the number of start times of an engine started by power supplied by the battery.

12. The battery abnormality indication apparatus as claimed in claim 4, wherein
the used amount is an accumulated value of a charged and discharged amount of the battery or the number of start times of an engine started by power supplied by the battery.

13. The battery abnormality indication apparatus as claimed in claim 5, wherein
the used amount is an accumulated value of a charged and discharged amount of the battery or the number of start times of an engine started by power supplied by the battery.

14. The battery abnormality indication apparatus as claimed in claim 6, wherein
the used amount is an accumulated value of a charged and discharged amount of the battery or the number of start times of an engine started by power supplied by the battery.

15. The battery abnormality indication apparatus as claimed in claim 7, wherein
the used amount is an accumulated value of a charged and discharged amount of the battery or the number of start times of an engine started by power supplied by the battery.

16. The battery abnormality indication apparatus as claimed in claim 8, wherein
the used amount is an accumulated value of a charged and discharged amount of the battery or the number of start times of an engine started by power supplied by the battery.

17. The battery abnormality indication apparatus as claimed in claim 1, wherein
when idling stop of an engine is inhibited due to a decrease in a capability of the battery that starts the engine, the electronic control unit determines that the battery has abnormality.

18. The battery abnormality indication apparatus as claimed in claim 2, wherein
when idling stop of an engine is inhibited due to a decrease in a capability of the battery that starts the engine, the electronic control unit determines that the battery has abnormality.

19. The battery abnormality indication apparatus as claimed in claim 3, wherein
when idling stop of an engine is inhibited due to a decrease in a capability of the battery that starts the engine, the electronic control unit determines that the battery has abnormality.

20. The battery abnormality indication apparatus as claimed in claim 4, wherein
when idling stop of an engine is inhibited due to a decrease in a capability of the battery that starts the engine, the electronic control unit determines that the battery has abnormality.
